(19) United States
(12) Patent Application Publication
(10) Pub. No.: US 2026/0122800 A1
(43) Pub. Date: Apr. 30, 2026

(54) DISPLAY DEVICE

(71) Applicant: LG ELECTRONICS INC., Seoul (KR)

(72) Inventors: Jaeuk RYU, Seoul (KR); Kuenyoung PARK, Seoul (KR)

(73) Assignee: LG ELECTRONICS INC., Seoul (KR)

(21) Appl. No.: 19/374,828

(22) Filed: Oct. 30, 2025

(30) Foreign Application Priority Data
Oct. 31, 2024 (KR) PCT/KR2024/016883

(51) Int. Cl. H05K 5/02

(52) U.S. Cl. CPC H05K 5/0217

(57) ABSTRACT

A display device is disclosed. The display device may include: a display panel; a frame positioned behind the display panel, a rear cover covering a rear of the frame; a bracket disposed between the frame and the rear cover; and a fastening member which couples the frame to the bracket, wherein the rear cover may include: a flat portion which faces a rear surface of the frame; a vertical portion bent forward from an edge of the flat portion; and a coupling portion bent from the vertical portion and facing the flat portion, and wherein the bracket may be disposed between the flat portion and the coupling portion and may be coupled to the coupling portion.

### CROSS-REFERENCE TO RELATED APPLICATION

Pursuant to 35 U.S.C. § 119, this application claims the benefit of an earlier filing date and right of priority to International Application No. PCT/KR2024/016883, filed on October 31, 2024, the contents of which are hereby incorporated by reference herein in its entirety.

### BACKGROUND OF THE INVENTION

### Field of the invention

The present disclosure relates to a display device.

### Description of the Related Art

With the development of information society, demand for various kinds of display devices is increasing. In response to this demand, various kinds of display devices, such as LCDs (Liquid Crystal Displays), PDPs (Plasma Display Panels), ELDs (Electro-luminescent Displays), VFDs (Vacuum Fluorescent Displays) and OLEDs (Organic Light-Emitting Diodes) have been recently researched and used.

Thereamong, an LCD panel includes a TFT substrate and a color substrate, which face each other with a liquid crystal layer interposed therebetween, in order to display an image using light supplied from a backlight unit. Meanwhile, an OLED panel is configured to display an image by depositing a self-luminescent organic layer on a substrate having a transparent electrode formed thereon.

In recent years, research to improve an assembly structure of a display device is being actively conducted.

### SUMMARY OF THE INVENTION

It is an object of the present disclosure to solve the above and other problems.

Another object of the present disclosure may be to provide a structure configured to couple a rear cover covering a rear of a frame to a frame.

Another object of the present disclosure may be to provide a structure configured to cover a rear of a frame by a rear cover and a back cover.

Another object of the present disclosure may be to provide a display device having the minimum thickness at a rear cover.

Another object of the present disclosure may be to provide a structure configured to reduce EMI (Electro Magnetic Interference) noise.

In order to accomplish the above and other objects, a display device according to one aspect of the present disclosure may include: a display panel; a frame positioned behind the display panel; a rear cover covering a rear of the frame; a bracket disposed between the frame and the rear cover; and a fastening member which couples the frame to the bracket, wherein the rear cover may include: a flat portion facing a rear surface of the frame; a vertical portion bent forward from an edge of the flat portion; and a coupling portion bent from the vertical portion and facing the flat portion, and wherein the bracket may be disposed between the flat portion and the coupling portion and may be coupled to the coupling portion.

### BRIEF DESCRIPTION OF THE DRAWINGS

The above and other objects, features and other advantages of the present disclosure will be more clearly understood from the following detailed description taken in conjunction with the accompanying drawings, in which:

FIGS. 1 to 18 are views illustrating display devices according to embodiments of the present disclosure.

### DETAILED DESCRIPTION

A description will now be given in detail according to exemplary embodiments disclosed herein, with reference to the accompanying drawings. For the sake of brevity of description with reference to the drawings, the same or equivalent components are denoted by the same reference numbers, and a description thereof will not be repeated.

In general, suffixes such as “module” and “unit” may be used to refer to elements or components. The use of such suffixes herein is merely intended to facilitate description of the specification, and the suffixes do not have any special meaning or function.

In the present disclosure, that which is well known to one of ordinary skill in the relevant art has generally been omitted for the sake of brevity. The accompanying drawings are used to facilitate understanding of various technical features, and it should be understood that the embodiments presented herein are not limited by the accompanying drawings. As such, the present disclosure should be construed to extend to any alterations, equivalents and substitutes, in addition to those that are particularly set out in the accompanying drawings.

It is to be understood that, although the terms “first,” “second,” etc. may be used herein to describe various elements, these elements should not be limited by these terms. These terms are only used to distinguish one element from another.

It will be understood that when an element is referred to as being “connected to” another element, intervening elements may be present. In contrast, it will be understood that when an element is referred to as being “directly connected to” another element, there are no intervening elements present.

A singular representation may include a plural representation unless the context clearly indicates otherwise.

In the present disclosure, it should be understood that the terms “comprises,” “includes,” “has,” etc. specify the presence of features, numbers, steps, operations, elements, components, or combinations thereof described in the specification, but do not preclude the presence or addition of one or more other features, numbers, steps, operations, elements, components, or combinations thereof.

Indication of directions of upward U, downward D, leftward Le, rightward Ri, forward F, and rearward R is merely for convenience of description, and the technical idea disclosed in the present disclosure is not limited thereto.

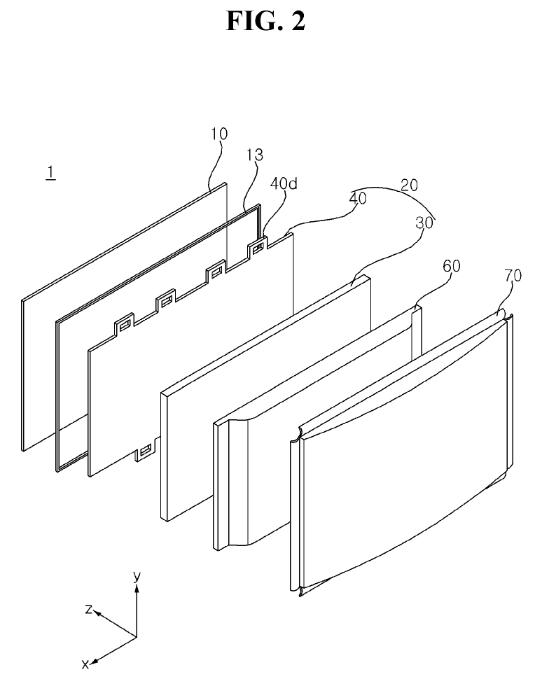

The display device according to the present disclosure may include an LCD panel which will be described later with reference to FIGS. 2 to 4. Alternatively, the display device may include various types of display panels such as an OLED (organic light emitting diode) display panel. When the display panel is an LCD panel, a backlight unit configured to provide the display panel with light is required. When the display panel is an OLED panel, the backlight unit is not required.

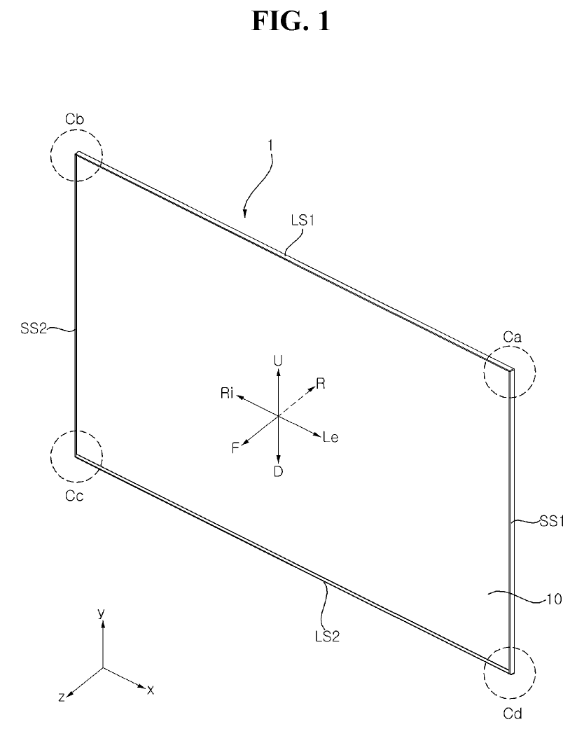

Referring to FIG. 1, the display device 1 may include a display 10. The display 10 may display an image.

The display device 1 may include a first long side LS1, a second long side LS2 opposed to the first long side LS1, a first short side SS1 adjacent to the first long side LS1 and the second long side LS2, and a second short side SS2 opposed to the first short side SS1. Although each of the first and second long sides LS1 and LS2 is illustrated and described as being longer than each of the first and second short sides SS1 and SS2 for convenience of explanation, the length of each of the first and second long sides LS1 and LS2 may be almost equal to that of each of the first and second short sides SS1 and SS2.

A direction parallel to the first and second long sides LS1 and LS2 of the display device 1 may be referred to as a lateral direction. A direction parallel to the first and second short sides SS1 and SS2 of the display device 1 may be referred to as a vertical direction. A direction perpendicular to the first and second long sides LS1 and LS2 and the first and second short sides SS1 and SS2 of the display device 1 may be referred to as a forward/backward direction.

A direction in which the display panel 10 displays an image may be referred to as forward F or z, and the opposite direction may be referred to as rearward R. The first long side LS1 may be referred to as an upper side U or y, and the second long side LS2 may be referred to as a lower side. The first short side SS1 may be referred to as a left side Le or x, and the second short side SS2 may be referred to as a right side Ri.

The first long side LS1, the second long side LS2, the first short side SS1 and the second short side SS2 may be referred to as an edge of the display device 1. The points at the first long side LS1, the second long side LS2, the first short side SS1 and the second short side SS2 meet each other may be referred to as corners.

The point at which the first short side SS1 and the first long side LS1 meet each other may be referred to as a first corner Ca. The point at which the first long side LS1 and the second short side SS2 meet each other may be referred to as a second corner Cb. The point at which the second short side SS2 and the second long side LS2 meet each other may be referred to as a third corner Cc. The point at which the second long side LS2 and the first short side SS1 meet each other may be referred to as a fourth corner Cd.

Referring to FIG. 2, the display device 1 may include the display panel 10, a guide panel 13, a backlight unit 20, a frame 60, and a back cover 70.

The display panel 10 may define the front face of the display device 1 so as to display an image. The display panel 10 may display an image by outputting red, green or blue of each of a plurality of pixels at specific times. The display panel 10 may be divided into an active area, in which an image is displayed, and an inactive area, in which an image is not displayed. The display panel 10 may include a front substrate and a rear substrate, which face each other with a liquid crystal layer interposed therebetween. The display panel 10 may be referred to as a liquid crystal display (LCD).

The front substrate may include a plurality of pixels, each of which is composed of red, green and blue sub-pixels. The front substrate may output light corresponding to red, green or blue in response to a control signal.

The rear substrate may include switching devices. The rear substrate may switch a pixel electrode. For example, the pixel electrode may change the molecular arrangement of the liquid crystal layer in response to a control signal. The liquid crystal layer may include liquid crystal molecules. The arrangement of the liquid crystal molecules may be changed according to the voltage difference between the pixel electrode and the common electrode. The liquid crystal layer may transmit the light supplied from the backlight unit 20 to the front substrate, or may obstruct the transmission of light.

The guide panel 13 may surround the periphery of the display panel 10 and may cover the lateral surfaces of the display panel 10. The guide panel 13 may be coupled to the display panel 10.

The backlight unit 20 may be positioned behind the display panel 10. The backlight unit 20 may include light sources. The backlight unit 20 may be positioned in the front of the frame 60, and may be coupled to the frame 60. The backlight unit 20 may be driven in a whole area driving manner or in a local area driving manner, such as local dimming driving or impulse driving. The backlight unit 20 may include an optical sheet 40 and an optical layer 30.

The optical sheet 40 may uniformly transmit the light from the light sources to the display panel 10. The optical sheet 40 may be composed of a plurality of layers. For example, the optical sheet 40 may include a prism sheet, a diffusion sheet and the like. For example, the optical sheet 40 may be a Dual Brightness Enhancement Film (DBEF). Meanwhile, a coupling portion 40d of the optical sheet 40 may be coupled to the guide panel 13 and/or the frame 60.

The frame 60 may be positioned behind the backlight unit 20 so as to support the components of the display device 1. For example, components such as the backlight unit 20 and a printed circuit board (PCB), on which a plurality of electronic components are positioned, may be coupled to the frame 60.

The back cover 70 may cover the rear surface of the frame 60. The back cover 70 may be coupled to the frame 60.

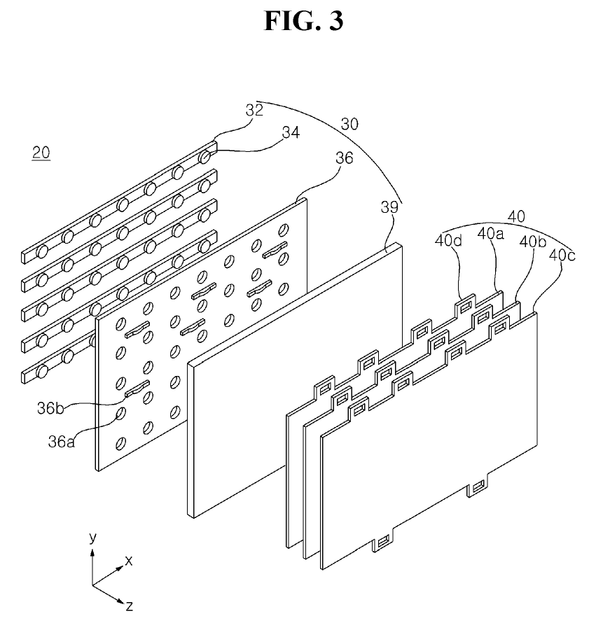

Referring to FIG. 3, the backlight unit 20 may include the optical layer 30 and the optical sheet 40. The optical layer 30 may include a substrate 32, at least one light source 34, a reflective sheet 36, and a diffusion plate 39.

The substrate 32 may be coupled to the front surface of the frame 60 (see FIG. 2). The substrate 32 may be composed of a plurality of straps which each have a plate shape and are spaced apart from each other in the vertical direction. Alternatively, the substrate 32 may have the form of a fork which includes an elongated first plate and a plurality of second plates which intersect the first plate. The substrate 32 may be composed of at least one of polyethylene terephthalate (PET), glass, polycarbonate (PC) or silicon. The substrate 32 may be a printed circuit board (PCB).

The at least one light source 34 may be mounted on the substrate 32. The plurality of light sources 34 may be spaced apart from each other on the substrate 32. An electrode pattern configured to connect an adapter to the light source 34 may be formed on the substrate 32. For example, a carbon nanotube electrode pattern configured to connect the light source 34 to the adapter may be formed on the substrate 32.

For example, the light source 34 may be a light-emitting diode (LED) chip or a light-emitting diode package including at least one light-emitting diode chip. The light source 34 may be composed of a colored LED configured to emit at least one color among red, green and blue or a white color LED. The colored LED may include at least one of a red LED, a green LED or a blue LED. The light source 34 may be referred to as a light assembly 34.

The reflective sheet 36 may be positioned in front of the substrate 32. The reflective sheet 36 may have a hole 36a in which the light source 34 is positioned. The reflective sheet 36 may include at least one reflective metal or reflective metal oxide. For example, the reflective sheet 36 may include metal and/or metal oxide having high reflectance, such as at least one of aluminum (Al), silver (Ag), gold (Au) or titanium dioxide (TiO2). For example, resin may be vapor-deposited or applied to the light source 34 and/or the reflective sheet 36. The resin may diffuse the light from the light source 34. Accordingly, the reflective sheet 36 may reflect the light from the light source 34 or the light reflected at the diffusion plate 39 forwards.

The diffusion plate 39 may be positioned in front of the reflective sheet 36. The diffusion plate 39 may diffuse the light from the light source 34. A support 36b may be positioned between the reflective sheet 36 and the diffusion plate 39 so as to support the rear surface of the diffusion plate 39. Consequently, an air gap may be formed between the reflective sheet 36 and the diffusion plate 39, and the light from the light source 34 may be widely diffused by virtue of the air gap. The diffusion plate 39 may be referred to as an optical plate 39.

The optical sheet 40 may be positioned in front of the diffusion plate 39. The rear surface of the optical sheet 40 may be in close contact with the diffusion plate 39, and the front surface of the optical sheet 40 may be in close contact with or adjacent to the rear surface of the display panel 10. The optical sheet 40 may include at least one sheet.

For example, the optical sheet 40 may include a plurality of sheets which have different functions. Each of a first optical sheet 40a and a second optical sheet 40b may be a prism sheet, and a third optical sheet 40a may be a diffusion sheet. The prism sheet may collect the light exiting from the diffusion plate 39 and may provide the light to the display panel 10. The diffusion sheet may prevent the light exiting from the diffusion plate 39 from being locally concentrated to more uniformly distribute the light. The number and/or position of the prism sheet and the diffusion sheet may be changed.

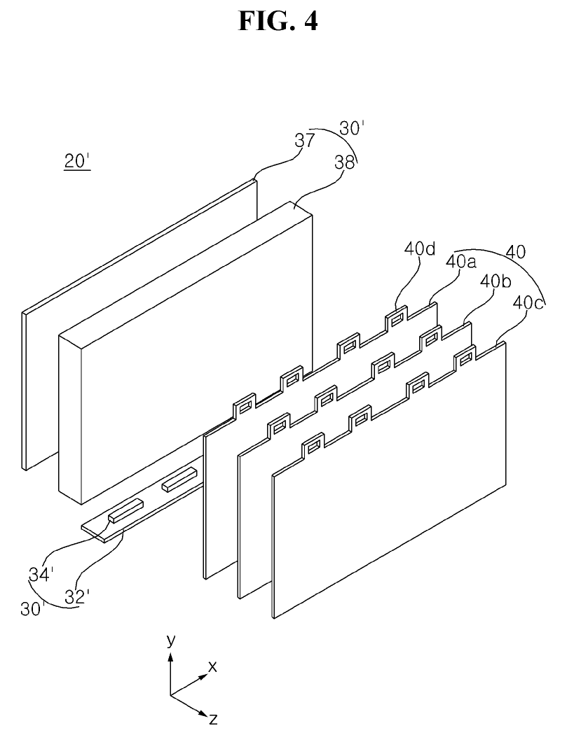

Referring to FIG. 4, the backlight unit 20’ may include the optical layer 30’ and the optical sheet 40. The optical layer 30’ may be positioned between the frame 60 (see FIG. 2) and the display panel 10 (see FIG. 2). The optical layer 30’ may be supported by the frame 60. The optical layer 30’ may include the substrate 32’, at least one light source 34’, the reflective sheet 37, and a light guide plate 38.

The light guide plate 38 may be positioned between the frame 60 (see FIG. 2) and the optical sheet 40 and may be supported by the frame 60. The light guide plate 38 may be referred to as an optical plate 38.

The substrate 32’ may be disposed adjacent to the periphery of the light guide plate 38 and may be coupled to one side of the guide panel 13 (see FIG. 2). For example, the substrate 32’ may be disposed adjacent to the lower side of the light guide plate 38. The substrate 32’ may be composed of at least one of polyethylene terephthalate (PET), glass, polycarbonate (PC) or silicon. The substrate 32’ may be a printed circuit board (PCB).

At least one light source 34’ may be mounted on the substrate 32’. The plurality of light sources 34’ may be spaced apart from each other on the substrate 32’. The electrode pattern configured to connect the adapter to the light source 34’ may be formed on the substrate 32’. For example, the carbon nanotube electrode pattern configured to connect the light source 34’ to the adapter may be formed on the substrate 32’.

For example, the light source 34’ may be a light emitting diode chip or a light emitting diode package including a light emitting diode chip. The light source 34’ may be composed of a colored LED configured to emit at least one color among red, green or blue or a white LED. The colored LED may include at least one of a red LED, a green LED or a blue LED. The light source 34’ may be referred to as a light assembly 34’.

The reflective sheet 37 may be positioned between the frame 60 (see FIG. 2) and the light guide plate 38 and may be supported by the frame 60. The reflective sheet 37 may include at least one of metal or metal oxide which is a reflective material. For example, the reflective sheet 37 may include metal and/or metal oxide having high reflectance such as at least one of aluminum (Al), silver (Ag), gold (Au) or titanium dioxide (TiO2).

Accordingly, the light source 34’ may provide light to the edge of the light guide plate 38. The light introduced into the light guide plate 38 may be directed forwards by means of the light guide plate 38 and the reflective sheet 37.

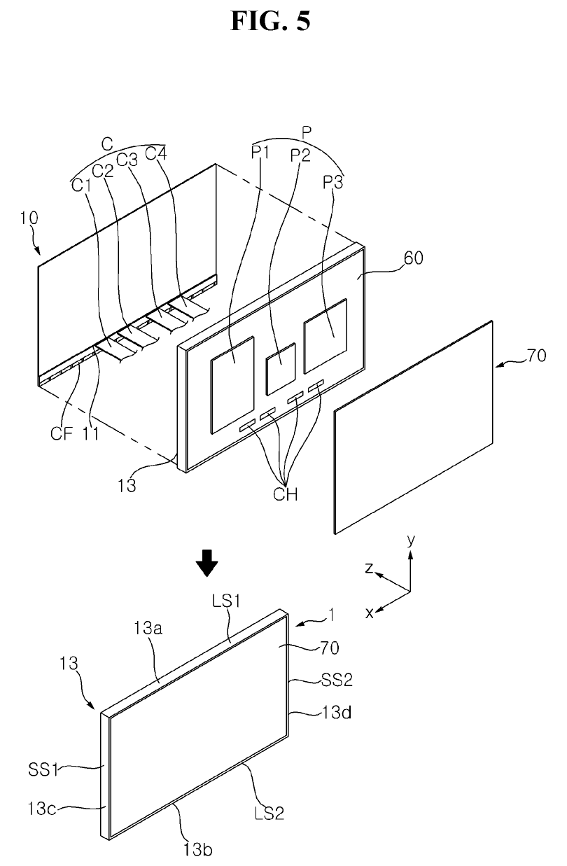

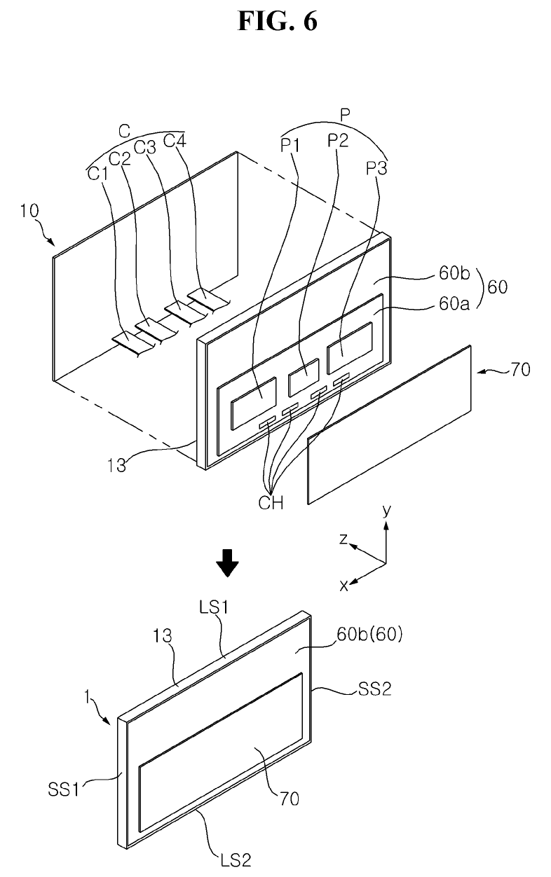

Referring to FIGS. 5 and 6, a board P may be coupled to the rear side of the frame 60. The frame 60 may be referred to as a cover bottom 60 or a module cover 60. A plurality of boards P may be electrically connected to electronic components. The board P may be a PCB, and electronic components may be mounted on the board P. A power supply board P1 may supply power to the components of the display device 1. A timing controller board P2 may provide the display panel 10 with a video signal. A main board P3 may control the components of the display device 1. For example, the power supply board P1 may be disposed adjacent to the left side of the frame 60, the main board P3 may be disposed adjacent to the right side of the frame 60, and the timing controller board P2 may be positioned between the power supply board P1 and the main board P3.

A cable C may be electrically connected to the display panel 10 and may be electrically connected to the timing controller board P2 through a hole CH formed in the frame 60. The cable C may be a flexible flat cable (FFC).

For example, the back cover 70 may have a surface area corresponding to the frame 60 (see FIG. 5). The back cover 70 may cover the rear side of the frame 60. The back cover 70 may cover the plurality of boards P.

For example, the back cover 70 may have a smaller surface area than the frame 60 (see FIG. 6). The plurality of boards P may be positioned at a first portion 60a of the frame 60, and the back cover 70 may cover the rear side of the first portion 60a. The plurality of boards P may be covered by the back cover 70, and the second portion 60b of the frame 60 may not be covered by the back cover 70. The first portion 60a may be a lower portion of the frame 60, and the second portion 60b may be an upper portion of the frame 60.

The guide panel 13 may form the edge of the display device 1. In other words, the guide panel 13 may form the long sides LS1 and LS2 and the short sides SS1 and SS2 of the display device 1. A first part 13a of the guide panel 13 may form the first long side LS1 and may be referred to as an upper part 13a. A second part 13b of the guide panel 13 may form the second long side LS2 and may be referred to as a lower part 14b. A third part 13c of the guide panel 13 may form the first short side SS1 and may be referred to as a left part 13c. A fourth part 13d of the guide panel 13 may form the second short side SS2 and may be referred to as a right part 13d.

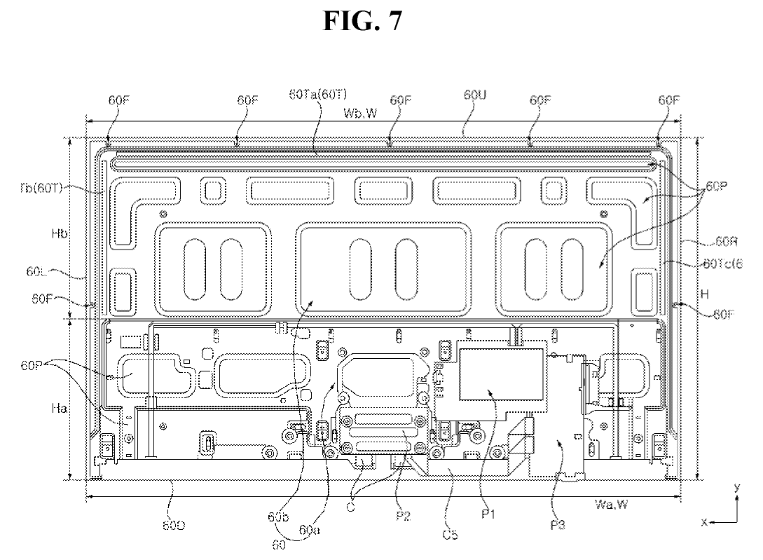

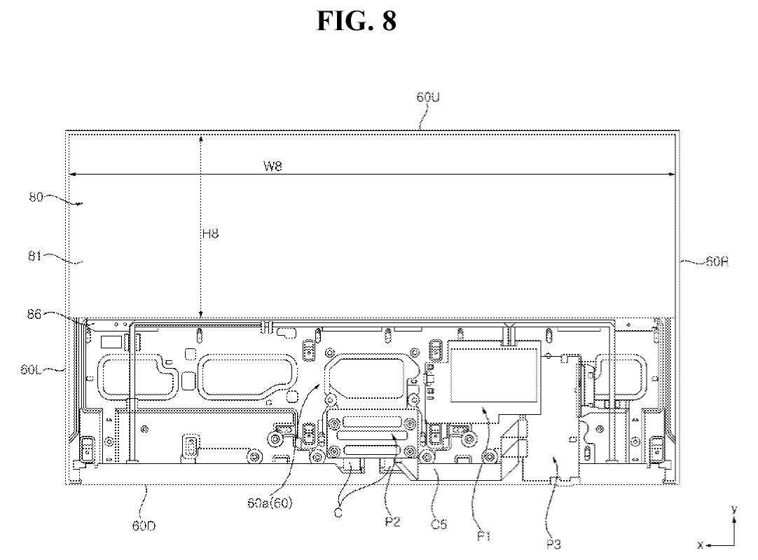

Referring to FIGS. 7 and 8, the frame 60 may have the shape of a quadrilateral plate. The upper side 60U and the lower side 60D of the frame 60 may be the long sides of the frame 60. The left side 60L and the right side 60R of the frame 60 may be the short sides of the frame 60. The frame 60 may include a plurality of pressed portions 60P. The pressed portions 60P may be formed by being pressed rearwards from the front surface of the frame 60 or by being pressed forwards from the rear surface of the frame 60. The pressed portions 60P may extend in a horizontal direction and/or vertical direction. The pressed portions 60P may improve the rigidity of the frame 60. The pressed portions 60P may be referred to as recessed portions 60P or beads 60P.

The first portion 60a may form a portion of the frame 60. The first portion 60a may be disposed adjacent to the lower side 60D of the frame 60 and may extend horizontally. The first portion 60a may be a lower portion of the frame 60. The first portion 60a may be referred to as a first region 60a or a lower region 60a.

The second portion 60b may form another portion of the frame 60. The second portion 60b may be disposed adjacent to the upper side 60U of the frame 60 and may extend horizontally. The second portion 60b may be an upper portion of the frame 60. The second portion 60b may be referred to as a second region 60b or an upper region 60b.

The width Wb of the second portion 60b may be equal to the width Wa of the first portion 60a. The width Wb may be equal to the width W of the frame 60, and the width W may be the distance between the left side 60L and the right side 60R of the frame 60. The height Hb of the second portion 60b may be equal to or slightly different from the height Ha of the first portion 60a. The height Hb may be equal to or slightly greater than the half of the height H of the frame 60, and the height H may be the distance between the upper side 60U and the lower side 60D of the frame 60.

The plurality of boards P may be coupled to the rear side of the first portion 60a of the frame 60. The power supply board P1, the timing controller board P2 and the main board P3 may be coupled to the rear side of the first portion 60a. The central line CL may be a vertical line which extends through the center of the frame 60. For example, the power supply board P1 and the main board P3 may be disposed on a right portion of the first portion 60a, that is, the portion between the central line CL and the right side 60R, and the timing controller board P2 may be disposed in the center of the first portion 60a. The timing controller board P2 may be electrically connected to the main board P3 via a cable C5. The main board P3 may be electrically connected to the power supply board P1 via a connector. Alternatively, the main board P3 and the power supply board P1 may be formed integrally with each other so as to constitute a single integrated board.

The pressed portions 60P may be formed on the first and second portions 60a and 60b of the frame 60.

The rear cover 80 may face the second portion 60b of the frame 60. The rear cover 80 may be coupled to the rear side of the second portion 60b and may cover the second portion 60b. The rear cover 80 may have a surface area corresponding to the second portion 60b of the frame 60. The width W8 and the height H8 of a flat portion 81 of the rear cover 80 may be equal to the width Wb and the height Hb of the second portion 60b. A fixing portion 86 of the rear cover 80 may project from the lower side of the flat portion 81 and may be coupled to the first portion 60a of the frame 60.

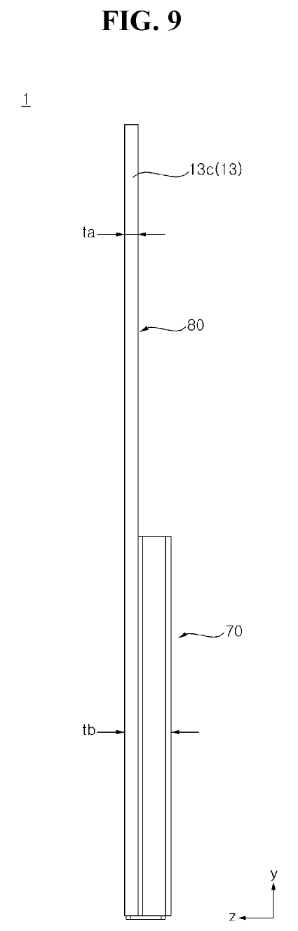

Referring to FIGS. 8 and 9, the back cover 70 may face the first portion 60a of the frame 60. The back cover 70 may be coupled to the rear side of the first portion 60a so as to cover the first portion 60a. The back cover 70 may have a surface area corresponding to the first portion 60a of the frame 60. The width and the height of the back cover 70 may be equal to the width Wa and the height Ha of the first portion 60a. Because the board P is disposed on the first portion 60a but is not disposed on the second portion 60b, the back cover 70 covering the first portion 60a may project rearwards farther than the rear cover 80 covering the second portion 60b (see reference numeral “e” of FIG. 9). In other words, the thickness ta of the first portion 60a of the display device 1 may be greater than the thickness tb of the second portion 60b of the display device 1. The thickness ta may be the distance between the front surface of the display panel 10 (see FIG. 1) and the rear surface of the back cover 70. The thickness tb may be the distance between the front surface of the display panel 10 (see FIG. 1) and the rear surface of the rear cover 80. The thickness tb may define the minimum thickness of the display device 1.

The back cover 70 may be referred to as a “first cover 70”, and the rear cover 80 may be referred to as a “second cover”. The back cover 70 and the rear cover 80 may be collectively referred to as a cover 70 and 80.

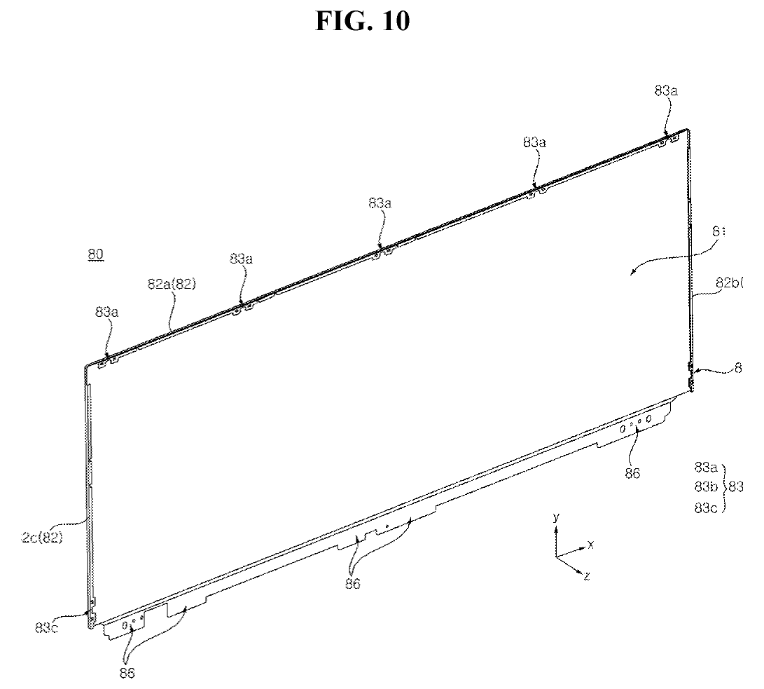

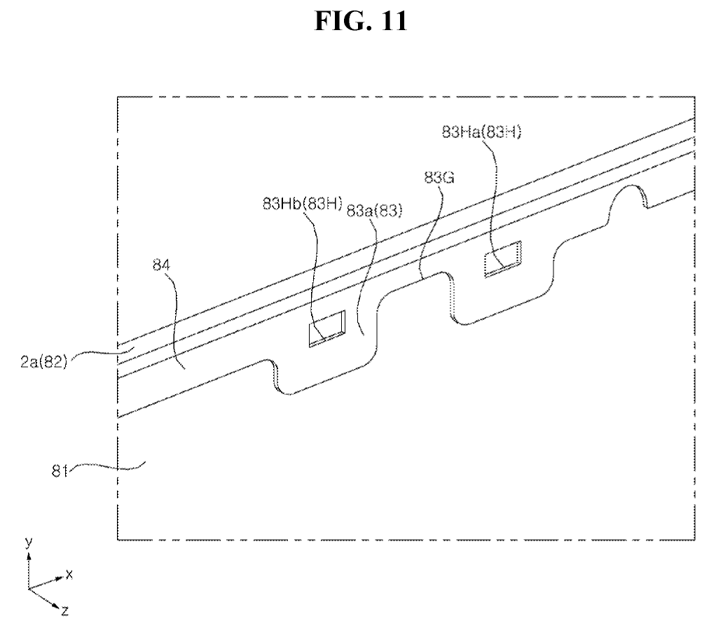

Referring to FIGS. 10 and 11, the rear cover 80 may have the shape of a quadrilateral plate overall. The rear cover 80 may include the flat portion 81 and a vertical portion 82. The flat portion 81 may be flat overall. The flat portion 81 may be referred to as a “flat plate portion 81” or a “body 81”. The vertical portion 82 may be bent at the edge of the flat portion 81. The vertical portion 82 may intersect the flat portion 81 and may extend along the edge of the flat portion 81. A first vertical portion 82a may be bent forwards at the upper side of the flat portion 81 and may extend along the upper side. A second vertical portion 82b may be bent forwards at the left side of the flat portion 81 and may extend along the left side. The third vertical portion 82c may be bent forwards at the right side of the flat portion 81 and may extend along the right side. The left end of the first vertical portion 82a may be connected to the upper end of the second vertical portion 82b, and the right end of the first vertical portion 82a may be connected to the upper end of the third vertical portion 82c.

A coupling portion 83 may be disposed adjacent to the front side of the vertical portion 82 and may project from the vertical portion 82 in a direction intersecting the vertical portion 82. The coupling portion 83 may be bent at the front side of the vertical portion 82 and may face the front surface of the flat portion 81. A coupling hole 83H may be formed in the coupling portion 83. The coupling hole 83H may be a quadrilateral hole. The coupling portion 83 may include a pair of coupling holes 83Ha and 83Hb which are spaced apart from each other in a width direction of the coupling portion 83. A groove 83G may be formed inwards from the end of the coupling portion 83 and may be positioned between the first coupling hole 83Ha and the second coupling hole 83Hb. A plurality of coupling portions 83a, 83b and 83c may be disposed along the vertical portion 82 and may have the same shape. The coupling portion 83 may be referred to as an “engaging portion 83”.

The first coupling portion 83a may be formed at the first vertical portion 82a. The first coupling portion 83a may be bent downwards at the front side of the first vertical portion 82a. A plurality of first coupling portions 83a may be spaced apart from each other along the first vertical portion 82a.

The second coupling portion 83b may be formed at the second vertical portion 82b. The second coupling portion 83b may be bent rightwards at the front side of the second vertical portion 82b. For example, the second coupling portion 83b may be disposed adjacent to the lower end of the second vertical portion 82b.

The third coupling portion 83c may be formed at the third vertical portion 82c. The third coupling portion 83c may be bent leftwards at the front side of the third vertical portion 82c. For example, the third coupling portion 83c may be disposed adjacent to the lower end of the third vertical portion 82c.

A horizontal portion 84 may be bent at the front side of the vertical portion 82 and may face the flat portion 81. The horizontal portion 84 may extend along the vertical portion 82. The coupling portion 83 may form a portion of the horizontal portion 84. The coupling portion 83 may project from the first vertical portion 82a farther from the remaining portion of the vertical portion 84. The first horizontal portion 84a may intersect the first vertical portion 82a, and the first coupling portion 83a may be formed at the first horizontal portion 84a. The second horizontal portion 84b may intersect the second vertical portion 82b, and the second coupling portion 83b may be formed at the second horizontal portion 84b. The third horizontal portion 84c may intersect the third vertical portion 82c, and the third coupling portion 83c may be formed at the third horizontal portion 84c.

The fixing portion 86 may project from the lower side of the flat portion 81. A plurality of fixing portions 86 may be disposed along the lower side of the flat portion 81. The fixing portion 86 may be coupled to the first portion 60a of the frame 60 (see FIG. 8).

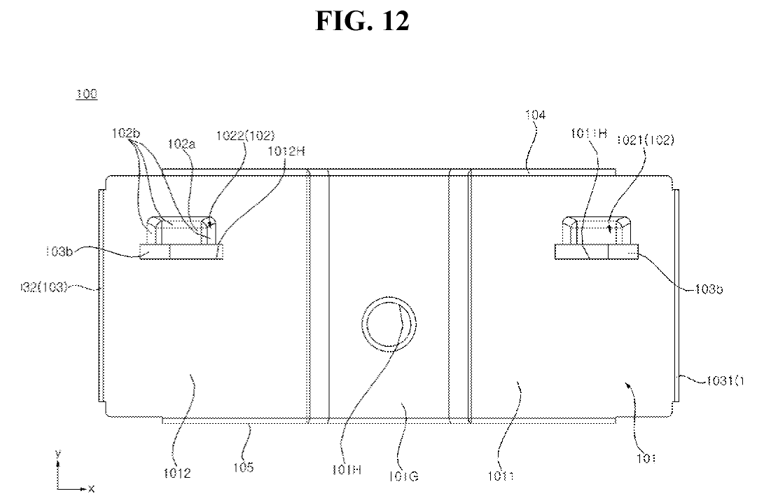

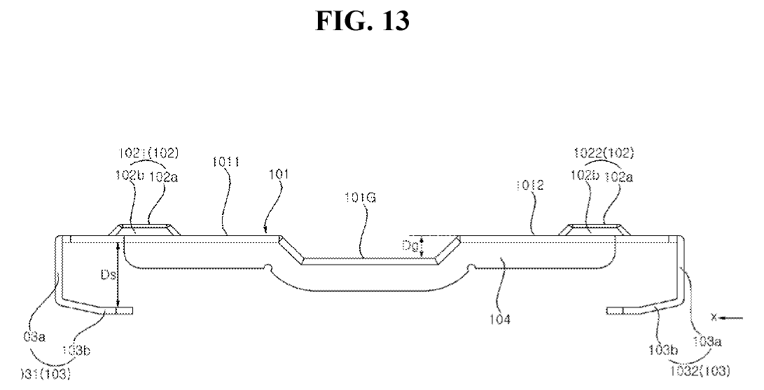

Referring to FIGS. 12 and 13, a bracket 100 may include a body 101, a projection 102 and a support 103. The bracket 100 may be referred to as a “holder 100”.

The body 101 may be formed so as to be flat. A depressed portion 101G may be formed by depressing the front surface of the body 101 rearwards (see a depressed depth Dg in FIG. 12). The depressed portion 101G may be formed in the center of the body 101. The depressed portion 101G may be formed so as to extend in the height direction of the body 101. A fastening hole 101H may be formed in the depressed portion 101G. A first coupling surface 1011 and a second coupling surface 1012 may be spaced apart from each other in the width direction of the body 101, and the depressed portion 101G may be positioned between the first coupling surface 1011 and the second coupling surface 1012. The first and second coupling surfaces 1011 and 1012 may define the front surface of the body 101.

The projection 102 may project from the front surface of the body 101. The projection 102 may be positioned adjacent to the upper side of the body 101. The front surface 102a of the projection 102 may be flat. A sloping surface 102b may be connected to the upper side, the left side and the right side of the front surface 102a and may be connected to the front surface of the body 101. The lower end of the projection 102 may be perpendicular to the front surface of the body 101. A first projection 1021 may project forwards from the first coupling surface 1011. A first hole 1011H may be formed in the first coupling surface 1011 adjacent to the first projection 1021. The second projection 1022 may project forwards from the second coupling surface 1012. A second hole 1012H may be formed in the second coupling surface 1012 adjacent to the second projection 1022.

The support 103 may be bent rearwards from the edge of the body 101. The support 103 may be bent at least once. The support 103 may include a first part 103a, which projects rearwards from the body 101, and a second part 103b, which is bent at the edge of the first part 103a and faces the body 101. The second part 103b may be spaced apart from the body 101 by a predetermined distance Ds. A first support 1031 may be bent rearwards at the left side of the body 101. The first part 103a of the first support 1031 may project rearwards from the left side of the body 101, and the second part 103b of the first support 1031 may be bent rightwards at the end of the first part 103a and may face the body 101. A second support 1032 may be bent rearwards at the right side of the body 101. The first part 103a of the second support 1032 may project rearwards from the right side of the body 101, and the second part 103b of the second support 1032 may be bent leftwards at the end of the first part 103a and may face the body 101. The support 103 may be elastic. The support 103 may include a metal such as stainless steel. The support 103 may be referred to as a “tension portion 103” or a “bent portion 103”.

A first rib 104 may project rearwards from the upper side of the body 101 and may extend along the upper side. A second rib 105 may project rearwards from the lower side of the body 101 and may extend along the lower side.

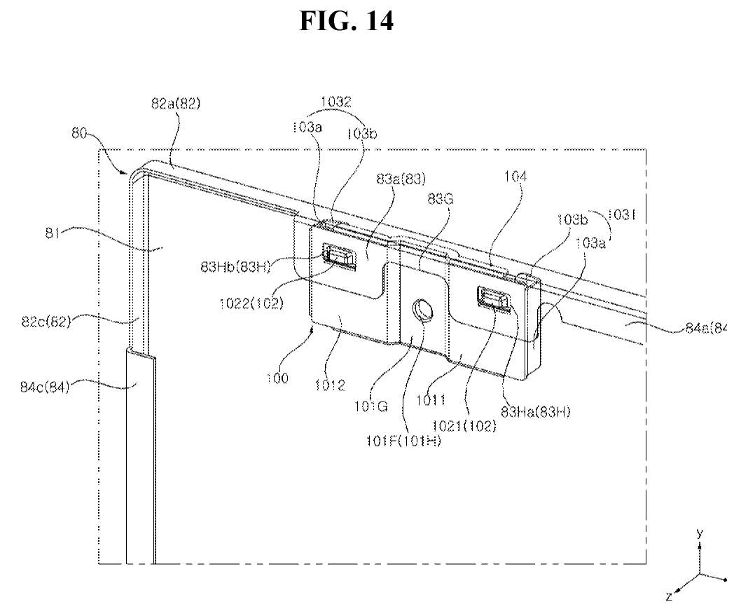

Referring to FIG. 14, the bracket 100 may be inserted between the first coupling portion 83a and the flat portion 81. The projection 102 of the bracket 100 may be coupled to the coupling hole 83H in the first coupling portion 83a. The first projection 1021 may be aligned with the first coupling hole 83Ha and may be engaged with the first coupling hole 83Ha. The second projection 1022 may be aligned with the second coupling hole 83Hb and may be engaged with the second coupling hole 83Hb. The projection 102 may be referred to as a “hook 102” or a “latch protrusion 102”.

Accordingly, the bracket 100 may be detachably coupled to the first coupling portion 83a of the rear cover 80. Similarly, the bracket 100 may be detachably coupled to the second coupling portion 83b (see FIG. 10) and the third coupling portion 83c (see FIG. 10) of the rear cover 80.

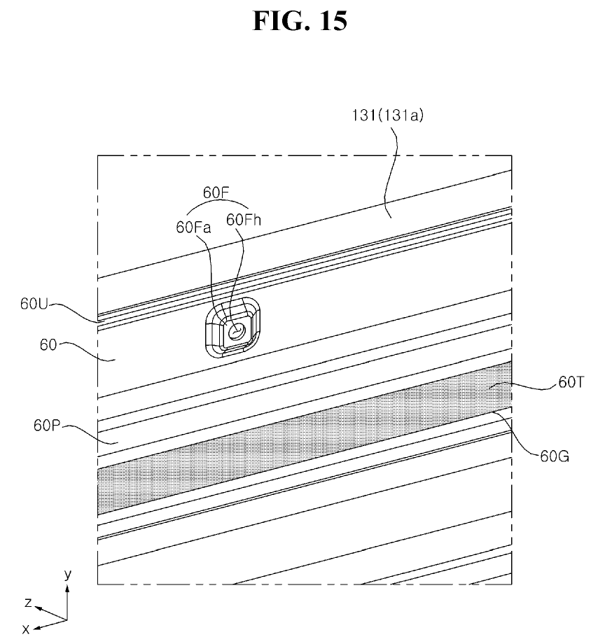

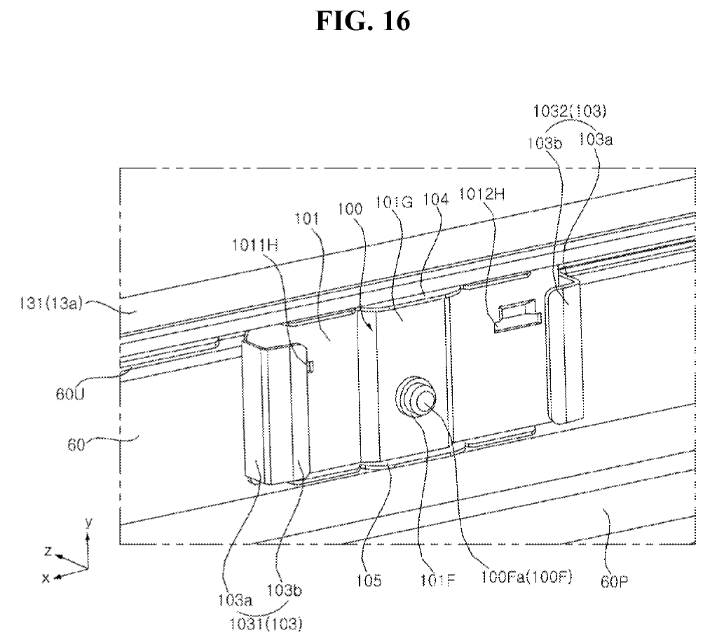

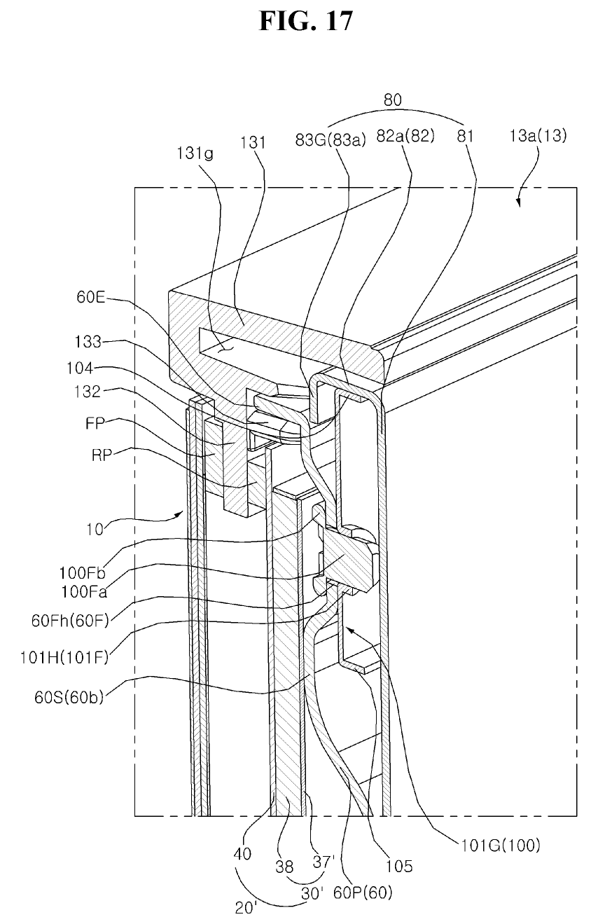

Referring to FIGS. 15 to 17, a fixing portion 60F may be formed at the frame 60. The frame 60F may be disposed adjacent to the edge of the frame 60. The fixing portion 60F may be formed by pressing the front surface of the frame 60 rearwards. The rear surface 60Fa of the fixing portion 60F may be flat. A through hole 60Fh may be formed in the rear surface 60Fa of the fixing portion 60F.

The bracket 100 may face the fixing portion 60F. A fastening portion 101F may project rearwards from the rear surface of the depressed portion 101G, and the fastening hole 101H may be formed in the fastening portion 101F. The inner peripheral surface of the fastening portion 101F, which defines the boundary of the fastening hole 101H, may include a threaded portion. The width of the fixing portion 60F may be equal to or less than the width of the depressed portion 101G. The groove 83G in the coupling portion 83 may be spaced apart from the fixing portion 60F so as not to interfere with the fixing portion 60F. The front surface of the depressed portion 101G may be positioned on the rear surface 60Fa of the fixing portion 60F. In other words, the fixing portion 60F may be inserted into the depressed portion 101G. The fastening hole 101H may be aligned with the through hole 60Fh in the fixing portion 60F.

A fastening member 100F may be inserted into and fastened to the fastening hole 101H in the bracket 100 through the through hole 60Fh in the fixing portion 60F. The fastening member 100F may be a screw. The body 100Fa of the fastening member 100F may be engaged with the threaded portion of the fastening portion 101F. The head 100Fb of the fastening member 100F may be formed at the front end of the body 100Fa and may be disposed adjacent to or engaged with the front surface of the fixing portion 60F.

Accordingly, the fastening member 100F may fix the frame 60 to the bracket 100 coupled to the first coupling portion 83a of the rear cover 80. Similarly, the fastening member 100F may fix the frame 60 to the bracket 100 coupled to the second coupling portion 83b (see FIG. 10) and the third coupling portion 83c (see FIG. 10) of the rear cover 80.

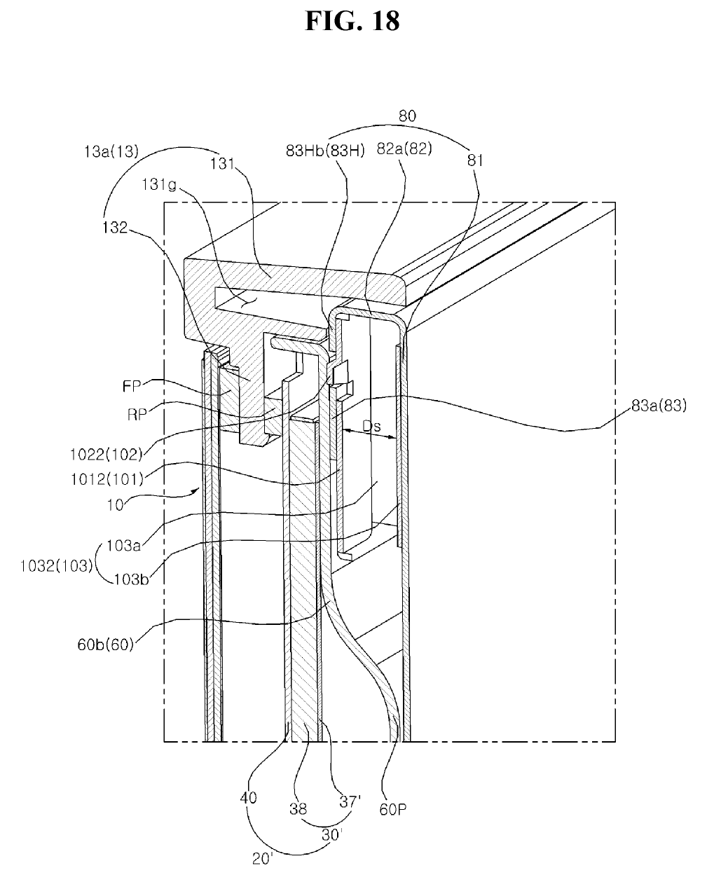

Referring to FIG. 18, the second part 103b of the support 103 may be in contact with the front surface of the flat portion 81. The distance between the body 101 and the second part 103b may be decreased by the flat portion 81. In other words, the second part 103b having elasticity may be pushed and elastically deformed by the flat portion 81, and the bracket 100 may be pressed between the coupling portion 83 and the flat portion 81. Consequently, the bracket 100 may be firmly coupled to the rear cover 80.

The coupling portion 83 may be in contact with the rear surface of the frame 60. The bracket 100 may be connected to the frame via the fastening member 100F. Each of the frame 60, the bracket 100 and the rear cover 80 may include a conductive material such as a metal. Consequently, it is possible to reduce EMI (Electro Magnetic interference) noise of electronic components mounted on the frame 60.

The guide panel 13 may include a vertical portion 131 and a horizontal portion 132. The vertical portion 131 may define the outer lateral surface of the guide panel 13 and may extend along the edge of the frame 60. The vertical portion 131 may cover the edge of the display panel 10 and the edge of the frame 60. The vertical portion 131 may cover the vertical portion 82 of the rear cover 80. A groove 131g may be formed in the vertical portion 131. The horizontal portion 132 may intersect the vertical portion 131 and may be positioned between the display panel 10 and the optical sheet 40. A front pad FP may be positioned between the rear surface of the display panel 10 and the horizontal portion 132, and a rear pad RP may be positioned between the horizontal pad 132 and the front surface of the optical sheet 40. A projection 133 may project toward the frame 60 from the horizontal portion 132 and may be spaced apart from the vertical portion 131.

The frame 60 may include a flat portion 60S, a pressed portion 60P and an insertion portion 60E. The flat portion 60S may be flat, and the coupling portion 83 of the rear cover 80 may be positioned on the flat portion 60S. The pressed portion 60P may be formed by pressing the flat portion 60S, and the flat portion 81 of the rear cover 80 may be disposed adjacent to the pressed portion 60P. The insertion portion 60E may be bent at the edge of the flat portion 60S and may be inserted into the groove between the projection 133 of the guide panel 13 and the vertical portion 131.

The rear surface of the rear cover 80 may be flush with the rear end of the guide panel 13 or may have a slight height difference with respect to the rear end of the guide panel 13 in a forward-and-rearward direction. In other words, the rear surface of the rear cover 80 may be positioned at the same level as or at a slightly different level from the rear end of the guide panel 13 in a forward-and-rearward direction.

Consequently, the rear cover 80 may be detachably coupled to the frame 60, and the height by which the rear cover 80 projects rearwards from the frame 60 may be minimized.

Meanwhile, the backlight unit 20’ may include the reflective sheet 37 which provides the display panel 10 with light and is positioned on the front surface of the frame 60. Alternatively, the backlight unit 20 (see FIG. 3) may include the substrate 32 which provides the display panel 10 with light and is positioned on the front surface of the frame 60.

Referring again to FIGS. 7 and 15, an adhesive member 60T may be coupled to the rear surface of the pressed portion 60P of the second portion 60b of the frame 60. A guide portion 60G may be depressed forwards from the rear surface of the pressed portion 60P, and the adhesive member 60T may be inserted into and coupled to the guide portion 60G. The depth of the guide portion 60G may be equal to or similar to the thickness of the adhesive member 60T. The guide portion 60G may be referred to as a “depressed portion 60G)”. The rear surface of the adhesive member 60T may be flush with the rear surface of the pressed portion 60P or may have a slight height difference with respect to the rear surface of the pressed portion 60P in a forward-and-rearward direction. In other words, the rear surface of the adhesive member 60T may be positioned at the same level as or at a slightly different level from the rear surface of the pressed portion 60P in a forward-and-rearward direction.

The adhesive member 60T may be coupled or attached to the front surface of the flat portion 81 (see FIG. 18) of the rear cover 80. The adhesive member 60T may be a double-sided adhesive tape. A first adhesive member 60Ta may be disposed adjacent to the upper side 60U of the frame 60 and may extend along the upper side 60U. A second adhesive member may be disposed adjacent to the left side 60L of the frame 60 and may extend along the left side 60L. A third adhesive member 60Tc may be disposed adjacent to the right side 60R of the frame 60 and may extend along the right side 60R.

Consequently, the rear cover 80 may be coupled to the frame 60 by means of the adhesive member 60T.

Referring to FIGS. 1 to 18, a display device 1 may include: a display panel 10; a frame 60 positioned behind the display panel 10; a rear cover 80 covering a rear of the frame 60; a bracket 100 disposed between the frame 60 and the rear cover 80; and a fastening member 100F which couples the frame 60 to the bracket 100, wherein the rear cover 80 may include: a flat portion 81 facing a rear surface of the frame 60; a vertical portion 82 bent forward from the edge of the flat portion 81; and a coupling portion 83 which is bent from the vertical portion 82 and which faces the flat portion 81, and wherein the bracket 100 may be disposed between the flat portion 81 and the coupling portion 83 and may be coupled to the coupling portion 83.

The bracket 100 may be adjacent to an edge of the frame 60.

The bracket 100 may include a plurality of brackets 100 disposed along the edge of the frame 60.

The coupling portion 83 may include a coupling hole 83H, and the bracket 100 may include a projection 102 which projects from a front surface of the bracket 100 and which is engaged with the coupling hole 83H.

The coupling hole 83H may include a pair of coupling holes 83Ha and 83Hb which are spaced apart from each other, and the projection 102 may include a pair of projections 1021 and 1022 which are engaged with the pair of coupling holes 83Ha and 83Hb.

The bracket 100 may further include: a body 101 which faces the coupling portion 83 and at which the projection 102 is formed; a depressed portion 101G depressed from a front surface of the body 101; and a fastening hole 101H formed at the depressed portion 101G, the frame 60 may include: a fixing portion 60F which is depressed toward the depressed portion 101G from a front surface of the frame 60 and at which the depressed portion 101G is positioned, and a through hole 60Fh which is formed at the fixing portion 60F and which is aligned with the fastening hole 101H, and the fastening member 100F may be fastened to the fastening hole 101H through the through hole 60Fh.

The fastening member 100F may include: a body 100Fa which is fastened to the fastening hole 101H through the through hole 60Fh; and a head 100Fb which is formed at a front end of the body 100Fa and is disposed adjacent to a front surface of the fixing portion 60F.

The bracket 100 may further include: a body 101 which faces the coupling portion 83 and at which the projection 102 is formed, and a support 103 which is bent rearward from an edge of the body 101 and which is in contact with the flat portion 81, wherein the support 103 may be elastically deformable by the flat portion 81.

The support 103 may include: a first part 103a projecting rearwards from the body 101, and a second part 103b which is bent from the first part 103a, which faces the body 101, and which is in contact with the flat portion 81.

The support 103 may include: a first support 1031 which is bent from a first side of the body 101 and which is in contact with the flat portion 81, and a second support 1032 which is bent from the second side of the body 101 opposed to the first side and which is in contact with the flat portion 81.

The display device 1 may further include an adhesive member 60T disposed between the frame 60 and the flat portion 81, and the frame 60 may include: a pressed portion 60P depressed rearwards from a front surface of the frame 60; and a guide portion 60G which is depressed forwards from a rear surface of the pressed portion 60P and at which the adhesive member 60T is positioned, wherein the adhesive member 60T may be coupled to the guide portion 60G and the flat portion 81.

Each of the frame 60, the rear cover 80 and the bracket 100 may have electrical conductivity.

The display device 1 may further include: a board P coupled to a rear of the frame 60; and a back cover 70 covering the board P, and the frame 60 may include: a first portion 60a at which the board P is positioned and to which the back cover 70 is coupled, and a second portion 60b to which the rear cover 80 is coupled.

A distance between a front surface of the display panel and a rear surface of the rear cover 80 may be less than a distance between the front surface of the display panel 10 and a rear surface of the back cover 70.

The display device 1 may further include a guide panel 13 which extends along an edge of the frame 60, and the guide panel 13 may cover an edge of the display panel 10, the edge of the frame 60 and an edge of the rear cover 80.

A display device 1 may include: a display panel 10; a frame 60 positioned behind the display panel 10; a rear cover 80 covering a rear of the frame 60; and a bracket 100 which is disposed between the frame 60 and the rear cover 80 and which is coupled to the frame 60 and the rear cover 80, wherein the bracket 100 may include: a first bracket adjacent to an upper side of the rear cover 80; a second bracket adjacent to a left side of the rear cover 80; and a third bracket adjacent to a right side of the rear cover 80.

The first bracket may include a plurality of first brackets disposed along the upper side of the rear cover 80, and the second and third brackets may be disposed adjacent to a lower side of the rear cover 80.

The rear cover 80 may include a fixing portion 86 which projects from a lower side of the rear cover 80 and which is coupled to the frame 60.

The display device 1 may further include a back cover 70 which is adjacent to the rear cover 80 and which is coupled to the rear of the frame 60.

A display device 1 may include: a display panel 10; a frame 60 positioned behind the display panel 10; a board P coupled to a rear of a first portion 60a of the frame 60; a back cover 70 covering the board P and coupled to first portion 60a; a rear cover 80 covering a rear of a second portion 60b of the frame 60; and a bracket 100 which is disposed between the frame 60 and the rear cover 80 and which is coupled to the frame 60 and the rear cover 80, wherein a distance between a front surface of the display panel 10 and a rear surface of the rear cover 80 may be less than a distance between the front surface of the display panel 10 and a rear surface of the back cover 70.

The effects of the display device according to the present disclosure will be described.

According to at least one embodiment of the present disclosure, it is possible to provide a structure in which the rear cover covering the rear of the frame is coupled to the frame.

According to at least one embodiment of the present disclosure, it is possible to provide a structure in which the rear cover and the back cover cover the rear of the frame.

According to at least one embodiment of the present disclosure, the thickness of the rear cover of a display device can be minimized.

According to at least one embodiment of the present disclosure, it is possible to provide a structure which reduces EMI (Electro Magnetic Interference) noise.

The additional scope of applicability of the present disclosure will be apparent from the above detailed description. However, those skilled in the art will appreciate that various modifications and alterations are possible, without departing from the idea and scope of the present disclosure, and therefore it should be understood that the detailed description and specific embodiments, such as the preferred embodiments of the present disclosure, are provided only for illustration.

Certain embodiments or other embodiments of the disclosure described above are not mutually exclusive or distinct from each other. Any or all elements of the embodiments of the disclosure described above may be combined with each other in configuration or function.

For example, a configuration “A” described in one embodiment of the disclosure and the drawings and a configuration “B” described in another embodiment of the disclosure and the drawings may be combined with each other. That is, even if the combination of the configurations is not explicitly described, the combination is possible except in the case where it is stated that the combination is impossible.

Although embodiments have been described with reference to a number of illustrative embodiments thereof, it should be understood that numerous other modifications and embodiments that fall within the scope of the principles of this disclosure can be devised by those skilled in the art. More particularly, various variations and modifications are possible in the component parts and/or arrangements within the scope of the disclosure, the drawings and the appended claims. In addition to variations and modifications in the component parts and/or arrangements, alternative uses will also be apparent to those skilled in the art.

What is claimed is:

1. A display device comprising:
a display panel;
a frame positioned behind the display panel;
a rear cover covering a rear of the frame;
a bracket disposed between the frame and the rear cover; and
a fastening member which couples the frame to the bracket,
wherein the rear cover comprises:
a flat portion facing a rear surface of the frame;
a vertical portion bent forward from an edge of the flat portion; and
a coupling portion bent from the vertical portion and facing the flat portion,
wherein the bracket is disposed between the flat portion and the coupling portion and is coupled to the coupling portion.

2. The display device of claim 1, wherein the bracket is adjacent to an edge of the frame.

3. The display device of claim 2, wherein the bracket is one of a plurality of brackets disposed along the edge of the frame.

4. The display device of claim 1, wherein the coupling portion comprises a coupling hole, and
wherein the bracket comprises a projection which projects from a front surface of the bracket and which is engaged with the coupling hole.

5. The display device of claim 4, wherein the coupling hole is one of a pair of coupling holes which are spaced apart from each other, and
wherein the projection comprises a pair of projections which are engaged with the pair of coupling holes.

6. The display device of claim 4, wherein:
the bracket further comprises:
a body which faces the coupling portion and at which the projection is formed;
a depressed portion at a front surface of the body; and
a fastening hole formed at the depressed portion, and
wherein the frame comprises:
a fixing portion protruding toward the depressed portion and comprising a through hole aligned with the fastening hole;
wherein the fastening member extends through the through hole to be fastened to the fastening hole.

7. The display device of claim 6, wherein the fastening member comprises:
a body fastened to the fastening hole; and
a head formed at a front end of the body and adjacent to a front surface of the fixing portion.

8. The display device of claim 4, wherein the bracket further comprises:
a body which faces the coupling portion and at which the projection is formed; and
a support bent rearward from an edge of the body and configured to be elastically deformed by contact with the flat portion of the rear cover.

9. The display device of claim 8, wherein the support comprises:
a first part bent rearward from the body; and
a second part bent from the first part and configured to contact the flat portion of the rear cover.

10. The display device of claim 8, wherein the support comprises:
a first support bent from a first side of the body and configured to contact the flat portion of the rear cover, and
a second support bent from a second side opposite the first side and configured to contact the flat portion of the rear cover.

11. The display device of claim 1, further comprising an adhesive member disposed between the frame and the flat portion of the rear cover,
wherein the frame comprises:
a pressed portion protruding rearward; and
a guide portion protruding forward from the pressed portion and at which the adhesive member is positioned,
wherein the adhesive member is coupled to the guide portion and the flat portion of the rear cover.

12. The display device of claim 1, wherein each of the frame, the rear cover, and the bracket are made of a material having electrical conductivity.

13. The display device of claim 1, further comprising:
a board coupled to a rear of the frame; and
a back cover covering the board,
wherein the frame comprises:
a first portion at which the board is positioned and to which the back cover is coupled; and
a second portion to which the rear cover is coupled.

14. The display device of claim 13, wherein a distance between a front surface of the display panel and a rear surface of the rear cover is less than a distance between the front surface of the display panel and a rear surface of the back cover.

15. The display device of claim 1, further comprising a guide panel extending along an edge of the frame,
wherein the guide panel covers an edge of the display panel, an edge of the frame, and an edge of the rear cover.

16. A display device comprising:
a display panel;
a frame positioned behind the display panel;
a rear cover covering a rear of the frame; and
a bracket disposed between the frame and the rear cover and coupled to the frame and the rear cover,
wherein the bracket comprises:
a first bracket adjacent to an upper side of the rear cover;
a second bracket adjacent to a left side of the rear cover; and
a third bracket adjacent to a right side of the rear cover.

17. The display device of claim 16, wherein the first bracket is one of a plurality of first brackets disposed along the upper side of the rear cover, and
wherein the second bracket and the third bracket positioned toward a lower side of the rear cover.

18. The display device of claim 16, wherein the rear cover comprises a fixing portion which projects from a lower side of the rear cover and which is coupled to the frame.

19. The display device of claim 16, further comprising a back cover adjacent to the rear cover and coupled to a rear of the frame.

20. A display device comprising:
a display panel;
a frame positioned behind the display panel;
a board coupled to a rear of a first portion of the frame;
a back cover covering the board and coupled to the first portion;
a rear cover covering a rear of a second portion of the frame; and
a bracket disposed between the frame and the rear cover and coupled to the frame and the rear cover,
wherein a distance between a front surface of the display panel and a rear surface of the rear cover is less than a distance between the front surface of the display panel and a rear surface of the back cover.
